(19) United States
(12) Patent Application Publication
(10) Pub. No.: US 2015/0076474 A1
(43) Pub. Date: Mar. 19, 2015

(54) METHOD FOR PACKAGING DISPLAY PANEL AND PACKAGING STRUCTURE OF DISPLAY PANEL

(71) Applicant: Innolux Corporation, Miao-Li County (TW)

(72) Inventors: Chi-Lun Kao, Miao-Li County (TW); Hao-Jung Huang, Miao-Li County (TW); Ker-Yih Kao, Miao-Li County (TW)

(21) Appl. No.: 14/483,193

(22) Filed: Sep. 11, 2014

(30) Foreign Application Priority Data
Sep. 18, 2013 (TW) 102133987

(51) Int. Cl. H01L 27/32; H01L 51/52

(52) U.S. Cl. CPC H01L 27/3244; H01L 27/3232; H01L 51/5262
USPC 257/40; 438/27

(57) ABSTRACT

A method for packaging display panel is provided. The method comprises following steps: providing a first substrate; pasting a frit on the first substrate; pre-sintering the frit in a specific temperature; forming a color filter unit on the first substrate; providing a second substrate oppositely disposed on the first substrate; and assembling the first substrate and the second substrate with the frit by way of laser sealing.

This application claims the benefit of Taiwan application Serial No. 102133987, filed Sep. 18, 2013, the disclosure of which is incorporated by reference herein in its entirety.

### TECHNICAL FIELD

The disclosure relates in general to a method for packaging display panel and a packaging structure of display panel, and more particularly to a method for packaging display panel and a packaging structure of display panel utilizing a frit to seal.

### BACKGROUND

The electronic component is easily broken by contacting moisture, so was display panel, the OLED (organic light-emitting) display especially. Since the OLED component is very sensitive to moisture and oxygen, it is necessary to seal the panel with adhesive having high impermeability and air tightness.

Traditional packaging method utilizes UV or thermosetting adhesive to sealing the panel. The UV and thermosetting adhesive can be hardened by projecting UV light or heating. However, the water vapor transmission rate (WVTR) of the UV adhesive is not good enough for OLED display. It is necessary to place extra drier inside the bottom emission OLED display to pervert the panel from short-circuiting.

There is a method for packaging display panel utilizes frit to replace the UV and thermosetting adhesive. Frit is an adhesive composed of inorganic material and has high impermeability and air tightness. However, frit must be pre-sintered to improve its consistency and stickiness before sealing the upper and lower substrates. The pre-sintering temperature usually up to 400° C., it is higher enough to damage the organic layer (such as color filter layer) in the substrate.

### SUMMARY

The disclosure is directed to a method for packaging display panel and a packaging structure of display panel utilize frit to seal upper and lower substrate. The method and the structure can achieve lower WVTR and have high quality.

According to one embodiment, a method for packaging display panel is provided. The method comprises following steps: providing a first substrate; pasting a frit on the first substrate; pre-sintering the frit in a specific temperature; forming a color filter unit on the first substrate after pre-sintering the frit; providing a second substrate oppositely disposed on the first substrate; and assembling the first substrate and the second substrate by way of laser sealing.

According to another embodiment, a packaging structure of display panel is provided. The package structure comprises a first substrate, a second substrate and a frit. The first substrate has a color filter unit, and the color filter unit is composed of at least one organic material. The second substrate has a display unit. The second substrate is opposite to the first substrate, and the display unit faces to the color filter unit. Frit disposed between the first substrate and the second substrate is for sealing the first substrate and the second substrate. The frit is formed in a ring round the color filter unit and the display unit. The frit comprises an organic residue of the organic material in its lateral side.

According to an alternative embodiment, a packaging structure of display panel is provided. The package structure comprises a first substrate, a second substrate and a frit. The first substrate has a color filter unit, and the color filter unit is composed of an organic material. The second substrate has a display unit. The display unit faces the color filter unit. Frit disposed between the first substrate and the second substrate is for sealing the first substrate and the second substrate. The frit has a surface doping region, and the surface doping region comprises a residue of the organic material.

The above and other aspects of the disclosure will become better understood with regard to the following detailed description of the non-limiting embodiment(s). The following description is made with reference to the accompanying drawings.

### BRIEF DESCRIPTION OF THE DRAWINGS

FIG. 1 illustrates a schematic diagram of a packaging structure according to one embodiment.

FIG. 2 is a flow chart shows the method for packaging display panel according to one embodiment.

FIGS. 3A to 3D shows a manufacturing process of packaging display panel according to FIG. 2.

FIG. 4 shows an enlarging top view of region A in FIG. 1.

FIG. 5 shows an enlarging cross section view of region A in FIG. 1.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

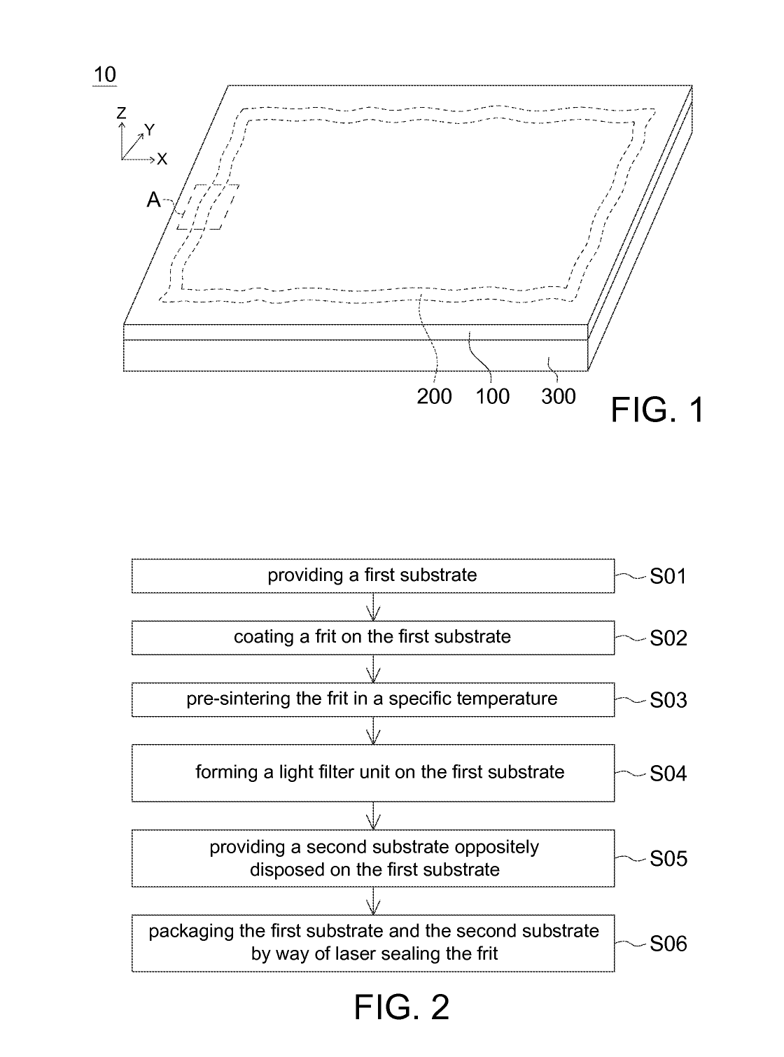

Referring to FIG. 1, a schematic diagram of packaging structure according to one embodiment is shown. The packaging structure 10 includes a first substrate 100, a frit 200 and a second substrate 300. The first substrate 100 is a color filter substrate. The second substrate 300 is an array substrate. The frit 200 is disposed between the first substrate 100 and the second substrate 300. Since frit 200 has high impermeability and air tightness, the packaging structure 10 has high water vapor transmission rate (WVTR) and is capable of being OLED display panel, or other display panel being sensitive to moisture and oxygen.

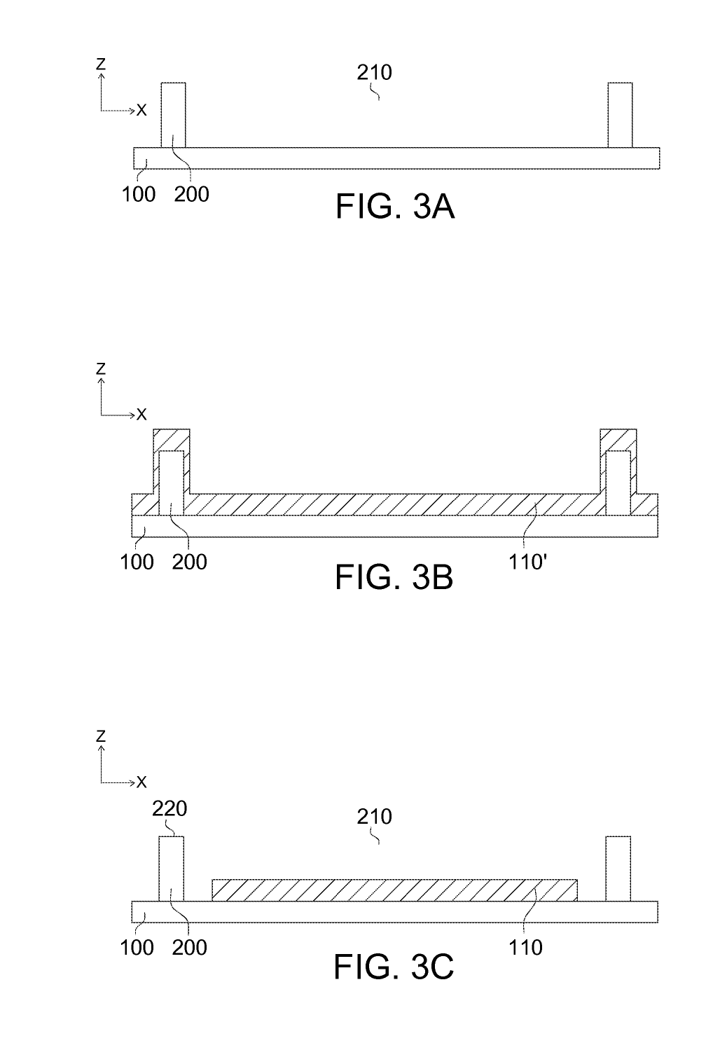

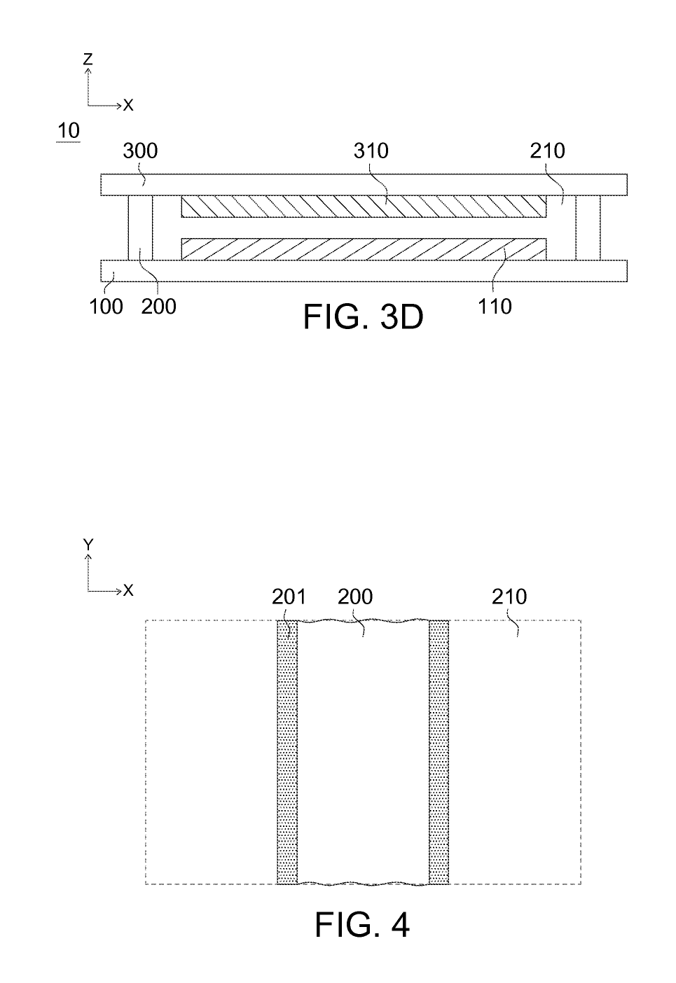

The method of forming packaging structure in FIG. 1 will be described following with FIGS. 2 to 3D. FIG. 2 is a flow chart shows the method for packaging display panel according to one embodiment, and FIGS. 3A to 3D shows a process of packaging display panel according to FIG. 2.

As shown in step S01 (FIG. 2) and FIG. 3A, a first substrate 100 is provided. The first substrate 100 is used to be a color filter substrate and is preferably a glass substrate. Then, as shown in step S02 (FIG. 2) and FIG. 3A, coating a frit 200 on the first substrate 100. The frit 200 can be coated on the edge of first substrate 100 by way of screen printing or dispensing. The frit 200 formed in a ring defines a storage space 210 on the first substrate 300.

Frit 200 is an adhesive having good water-resistance. Frit is an inorganic adhesive for sealing first substrate 100 in the following process. The composition of frit 200 includes metal oxide or oxide glasses, such as PbO, Bi₂O₃, SiO₂, B₂O₃, P₂O₅, ZnO and Al₂O₃. The composition can be one of them or the combination thereof, which is not limited thereto.

For improving the water-resistance of the frit 200, the pre-sintering step S03 in FIG. 2 is performed. The pre-sintering process uses specific heat source heating the frit 200 to increase the densification of the frit 200 and the adhesion between the frit 200 and the first substrate 100. The specific heat source includes laser, infrared and oven, and oven is preferred. The heating region of laser is narrow, so as to prevent the color filter layer on substrate from heat damage. However, the high energy and high moving speed of laser may cause bubble or crack occurred inside the frit 200. Furthermore, the starting portion of the laser heating path and the ending portion of the laser heating path are overlapped, and the overlapped region is easily cracked because the laser irradiated the overlapped region twice. The density of the frit 200 in the overlapped region would be different from that in other regions. In present embodiment, the specific heat source is oven which provides uniform, stable and periodical heat energy. As shown in FIG. 3A, frit 200 is the only thing disposed on the first substrate 100. Since first substrate 100 has good heat resistant, the first substrate 100 and the frit 200 are heated in the oven simultaneously. The pre-sintering temperature and time are depend on the frit, and usually in 300° C.-550° C. (normally, high than 400° C.).

As shown in step S04 (FIG. 2) and FIG. 308, depositing a color filter material 110′ to cover the first substrate 100 and frit 200. Then patterning the color filter material 110′ by ways of photolithographic process to from a color filter layer unit 110 in the storage space 210. To be specifically, the pattern of color filter layer is defined by exposure process first, and then the redundant portion of color filter material 110′ is removed to form the color filter unit 110.

The color filter material 110′ is an organic material such as color photoresist, and the redundant portion means the color filter material outside the pixel display area. For example, the color filter material 110′ on a top surface 220 of the frit 200 must be removed to assure the good adhesion of the frit 200. For simplifying the drawing, FIG. 3B only shows single color filter layer 110. In practical manufacturing process, three color filter material with three different colors individually can be deposited, and then removing the redundant portion to from color filter unit 110 with three color filter layers (red, blue and green). The color filter substrate in FIG. 3C is accomplish after forming the color filter unit 110.

As mentioned above, the color filter material is composed of organic material and the color filter material will be damaged at pre-sintering temperature (>400° C.). The invention use new process to keep quality both the color filter unit and the frit.

The packaging structure of display panel may further include a black matrix layer (not shown). When the composition of the black matrix layer is resin, the black matrix layer and the color filter unit are formed after pre-sintering step. When the composition of the black matrix is metal or alloy, such as chromium (Cr), the black matrix layer can be formed on the first substrate 100 before the forming of frit 200. The metal or alloy won't be damaged by high pre-sintering temperature.

Next, as shown in step S05 (FIG. 2) and FIG. 3D, providing a second substrate 300 being opposite to the first substrate 100. The second substrate 300 is a array substrate having a display unit 310. When assembling the first substrate 100 and the second substrate 300, the second substrate 300 contacts the frit 200 and the display unit 310 is disposed into the storage space 210, so that the display unit 310 faces the color filter unit 110. In one embodiment, the display unit is an organic emission layer.

Finally, as shown in step S06 (FIG. 2), projecting high power laser on the connecting region of the second substrate 300 overlaying with the frit 200, and melting the part of the frit 200 contacted with the second substrate 300 to seal the first substrate 100 and the second substrate 300, and then accomplishing the packaging structure 10 are shown in FIG. 3D. Generally the laser temperature is higher than the pre-sintering temperature, for example, over 600° C. The power of laser and the irradiated time is depend on the material of the frit 200, and is not limited thereto.

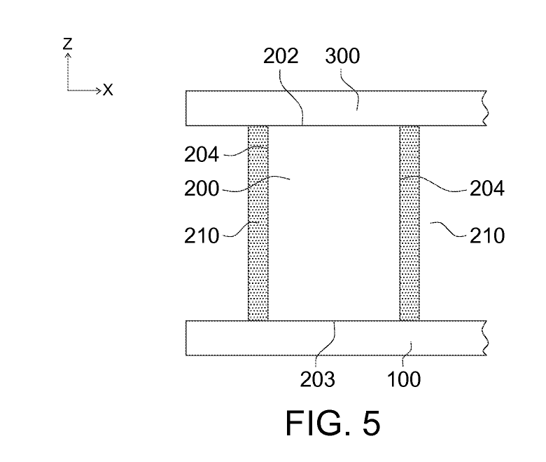

The other packaging structure 10 according to above manufacturing process is shown in FIGS. 4-5. FIG. 4 shows an enlarging top view corresponding to region A of FIG. 1, and FIG. 5 shows an enlarging cross section view corresponding to region A of FIG. 1. The frit 200 has a top surface 202 contacted to the second substrate 300, a bottom surface 203 contacted to the first substrate 100, and two lateral sides 204 connecting the top surface 202 and the bottom surface 203. Furthermore, the frit 200 includes a surface doping region 201 in the lateral sides 204. The composition of the surface doping region 201 includes the organic residue of color filter material 110′. A part of the color filter material 110′ (from step S04—forming color filter unit 110, FIG. 3B) permeates into the frit 200, and is carbonized to form an organic residue in the step of laser sealing S06. In one embodiment, the organic residue is shown burned black in the optical microscope. In another embodiment, the organic residue can be detected by material analysis if the amount of the organic residue is few. In one embodiment, the distribution width of the organic residue in the frit 200 is between 0.01-3 μm. In other words, the surface doping region 201 in one of the lateral sides is 0.01-3 μm. The distribution width can keep the adhesion of the frit and the water-resistance.

The method for packaging display panel and packaging structure of display panel disclose above utilize the frit to seal the color filter substrate and the array substrate. The frit is pre-sintered before formation of the color filter layer, so the pre-sintering process will not damage color filter layer and can be performed in the oven. Oven provides an even and moderate heat source, and is good for improving the consistency of the frit. This method avoids the problem of generating bubbles, crack or opening in the frit by laser pre-sintering, so packaging structure of display panel according to the disclosure has low water vapor transmission rate and good packaging quality.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A method for packaging display panel, comprising:
providing a first substrate;
pasting a frit on the first substrate;
pre-sintering the frit in a specific temperature;
forming a color filter unit on the first substrate after pre-sintering the frit;
providing a second substrate oppositely disposed on the first substrate; and
assembling the first substrate and the second substrate with the frit by way of laser sealing.

2. The method according to claim 1, wherein forming the color filter unit comprises:
depositing at least one organic material covering the first substrate and the frit; and
patterning the organic material and removing the part of the organic material covering the frit to form the color filter unit by photolithographic process.

3. The method according to claim 1, wherein in the step of pre-sintering the frit, the first substrate with the frit is pre-sintered in an over.

4. The method according to claim 3, wherein the specific temperature of pre-sintering is between 300 and 550° C.

5. The method according to claim 1, wherein in the step of assembling the first substrate and the second substrate, the laser sealing is to irradiating the connecting region of the second substrate overlaying with the frit by laser.

6. The method according to claim 1, wherein the color filter unit comprises a red color filter layer, a green color filter layer and a blue color filter layer.

7. The method according to claim 6, wherein the second substrate is an array substrate comprising a display unit, and the display unit is opposite to the color filter unit.

8. The method according to claim 7, wherein the display unit of the second substrate is an organic emission layer.

9. A packaging structure of display panel, comprising:
a first substrate having a color filter unit, wherein the color filter unit is composed of at least one organic material;
a second substrate having a display unit, wherein the second substrate is opposite to the first substrate, and the display unit faces the color filter unit; and
a frit disposed between the first substrate and the second substrate for sealing the first substrate and the second substrate, wherein the frit is formed in a ring round the color filter unit and the display unit,
wherein the frit comprises an organic residue of the organic material in two lateral sides of the frit.

10. The packaging structure according to claim 9, wherein a temperature of the pre-sintering process of the frit is between 300-550° C.

11. The packaging structure according to claim 9, wherein a distribution range of the organic residue in the lateral side of the frit is between 0.01-3 μm.

12. The packaging structure according to claim 9, wherein the organic residue in the frit is a remaining product after exposing a organic material to form the color filter unit by photolithographic process.

13. The packaging structure according to claim 9, wherein the display unit is an organic emission layer.

14. The packaging structure according to claim 9, wherein the color filter unit comprises a red color filter layer, a green color filter layer and a blue color filter layer.

15. A packaging structure of display panel, comprising:
a first substrate having a color filter unit, wherein the color filter unit is composed of an organic material;
a second substrate having a display unit, wherein the display unit faces the color filter unit; and
a frit disposed between the first substrate and the second substrate for sealing the first substrate and the second substrate,
wherein the frit has a surface doping region, and the surface doping region comprises an organic residue of the organic material.

16. The packaging structure according to claim 15, wherein a distribution range of the surface doping region is between 0.01-3 μm.

17. The packaging structure according to claim 15, wherein the frit has a top surface connected to the second substrate, a bottom surface connected to the first substrate, and a lateral side connected between the first and second substrates, wherein the surface doping region is disposed in the lateral side.
